(19) United States
(12) Patent Application Publication
(10) Pub. No.: US 2025/0221071 A1
(43) Pub. Date: Jul. 3, 2025

(54) IMAGE SENSING DEVICE

(71) Applicant: SK hynix Inc., Icheon-si (KR)

(72) Inventor: Min Su CHO, Icheon-si (KR)

(21) Appl. No.: 18/668,973

(22) Filed: May 20, 2024

(30) Foreign Application Priority Data
Jan. 2, 2024 (KR) 10-2024-0000121

(51) Int. Cl. H01L 27/146

(52) U.S. Cl. CPC H10F 39/8053; H10F 39/182; H10F 39/8063; H10F 39/807

(57) ABSTRACT

Image sensing devices are disclosed. In an embodiment, an image sensing device may include: a lower layer including a substrate and a plurality of photodetectors such as photodiodes; an upper layer disposed over the lower layer; a first meta-lens layer disposed over the upper layer and configured to focus incident light; and a second meta-lens layer disposed below the lower layer and configured to scatter or reflect the incident light toward the photodetector.

### PRIORITY CLAIM AND CROSS REFERENCE TO RELATED APPLICATIONS

This patent document claims the priority and benefits of Korean Patent Application No. 10-2024-0000121, filed on Jan. 2, 2024, which is incorporated by reference in its entirety as part of the disclosure of this patent document.

### TECHNICAL FIELD

Various embodiments of the disclosed technology relate to an image sensing device capable of reducing a pixel size without increasing an epitaxial (Epi) thickness.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device that has a cavity resonance structure, thereby minimizing the epitaxial (Epi) thickness.

In an embodiment, an image sensing device may include: a lower layer including a substrate and a plurality of photodetectors; an upper layer disposed over the lower layer; a first meta-lens layer disposed over the upper layer and configured to focus incident light; and a second meta-lens layer disposed below the lower layer and configured to scatter or reflect the incident light toward the photodetectors.

In an embodiment, an image sensing device may include: a lower layer including a substrate and a plurality of photodetectors; an upper layer disposed over the lower layer; a first meta-lens layer disposed over the upper layer and configured to focus incident light; and a second meta-lens layer disposed below the lower layer and configured to scatter or reflect the incident light toward the or reflect the incident light from the photodetectors, wherein the first meta-lens layer and the second meta-lens layer have different transmittances from each other.

In an embodiment, an image sensing device may include: a first layer including a substrate and a plurality of photodetectors; a second layer disposed over the first layer and including a plurality of infrared filters; a first meta-lens layer disposed over the second layer and configured to focus incident light onto each of the infrared filters; and a second meta-lens layer disposed below the first layer and configured to scatter or reflect the incident light toward the photodetector. In an embodiment, an image sensing device may include: a lower layer including a substrate and a plurality of photodetectors; an upper layer disposed over the lower layer; a first meta-lens layer disposed over the upper layer and configured to focus incident light onto each of the photodetectors; and a second meta-lens layer disposed below the lower layer and configured to scatter or reflect the incident light toward the photodetector.

In an embodiment, an image sensing device may include: a lower layer including a substrate and a plurality of photodiodes; an upper layer disposed over the lower layer; a first meta-lens layer disposed over the upper layer and to focus incident light; and a second meta-lens layer disposed below the lower layer and configured to scatter or reflect the incident light toward the photodiode. In some implementations, the term “meta-lens” can be used to indicate a lens that is made by placing nanostructures on a surface to give light a customized phase, polarization, and amplitude.

In an implementation, the plurality of photodiodes is formed in one region of the substrate, and the lower layer may include a plurality of first isolation regions formed between adjacent photodiodes of the plurality of photodiodes.

In an implementation, the upper layer may include: a plurality of color filters formed over the lower layer (e.g., the substrate including the photodiodes); and a plurality of second isolation regions formed between adjacent color filters of the plurality of color filters.

In an implementation, the plurality of color filters may include one or more red color filters, one or more green color filters, and one or more blue color filters. In an implementation, the first meta-lens layer may include a plurality of nanostructures and may refract the incident light such that light rays of the incident light at a red wavelength are focused onto the one or more red color filters, light rays of the incident light at a green wavelength are focused onto the one or more green color filters, light rays of the incident light at a blue wavelength are focused onto the one or more blue color filters.

In an implementation, the second meta-lens layer may include a plurality of nanostructures and may reflect, toward the lower layer, the incident light that passes through the lower layer.

In an implementation, when the incident light is incident on a surface of the second meta-lens layer at a right angle, the second meta-lens layer may direct the light from reflected from the second meta-lens layer toward sidewalls of the first isolation regions formed between the adjacent photodiodes.

In an implementation, the second meta-lens layer may reflect the incident light such that the light rays of the incident light at the red wavelength reflected from the second meta-lens layer and passing through the lower layer are focused onto the photodiode below the red color filter, the light rays of the incident light at the green wavelength reflected from the second meta-lens layer and passing through the lower layer are focused onto the photodiode below the green color filter, and the light rays of the incident light at the blue wavelength reflected from the second meta-lens layer and passing through the lower layer are focused onto the photodiode below the blue color filter.

In another embodiment, an image sensing device may include: a lower layer including a substrate and a plurality of photodiodes; an upper layer disposed over the lower layer; a first meta-lens layer disposed over the upper layer and configured to focus incident light toward the lower layer disposed below the upper layer; and a second meta-lens layer disposed below the lower layer and configured to scatter or reflect the incident light toward the photodiode, wherein the first meta-lens layer and the second meta-lens layer may have different transmittances from each other.

In another embodiment, an image sensing device may include: a first layer including a substrate and a plurality of photodiodes; a second layer disposed over the first layer and including a plurality of infrared filters; a first meta-lens layer disposed over the second layer and configured to focus incident light onto each of the infrared filters; and a second meta-lens layer disposed below the first layer and configured to scatter or reflect the incident light toward the photodiode.

In an implementation, the plurality of photodiodes is formed in one region of the substrate, and the first layer further includes a plurality of first isolation regions formed between adjacent photodiodes of the plurality of photodiodes.

In an implementation, the plurality of infrared filters is formed over the substrate, and the second layer includes a plurality of second isolation regions formed between adjacent infrared filters of the plurality of infrared filters.

In an implementation, the first meta-lens layer may include a plurality of nanostructures and may refract the incident light such that the incident light is focused onto each of the infrared filters.

In an implementation, the second meta-lens layer may include a plurality of nanostructures and may reflect, toward the first layer, the incident light that passes through the first layer.

In another embodiment, an image sensing device may include: a lower layer including a substrate and a plurality of photodiodes; an upper layer disposed over the lower layer; a first meta-lens layer disposed over the upper layer and configured to focus incident light onto each of the photodiodes; and a second meta-lens layer disposed below the lower layer and configured to scatter or reflect the incident light on the photodiode.

In an implementation, the plurality of photodiodes is formed in one region of the substrate, and the lower layer further includes a plurality of first isolation regions formed between adjacent photodiodes of the plurality of photodiodes.

In an implementation, the upper layer may include a plurality of second isolation regions formed over the plurality of first isolation regions.

In an implementation, the plurality of photodiodes may include: a first photodiode that receives light with a red wavelength; a second photodiode that receives light with a green wavelength; and a third photodiode that receives light with a blue wavelength. In an implementation, the first meta-lens layer may include a plurality of nanostructures and may refract the incident light such that light rays of the incident light at the red wavelength are focused onto the first photodiode, light rays of the incident light at the green wavelength are focused onto the second photodiode, and light rays of the incident light at the blue wavelength are focused onto the third photodiode.

In an implementation, the second meta-lens layer may include a plurality of nanostructures and may reflect, toward the lower layer, the incident light that passes through the lower layer.

In an implementation, the second meta-lens layer may reflect the incident light such that the light rays of the incident light at the red wavelength reflected from the second meta-lens layer and passing through the lower layer are focused onto the first photodiode, the light rays of the incident light at the green wavelength reflected from the second meta-lens layer and passing through the lower layer are focused onto the adjacent second photodiode, and the light rays of the incident light at the blue wavelength reflected from the second meta-lens layer and passing through the lower layer are focused onto the third photodiode.

### BRIEF DESCRIPTION OF THE DRAWINGS

FIG. 1 is a block diagram of an image sensing device based on an embodiment of the disclosed technology.

FIG. 2 shows an example of a pixel array based on an embodiment of the disclosed technology.

FIG. 3 shows an example of a pixel array based on an embodiment of the disclosed technology.

FIG. 4 shows an example of a pixel array based on an embodiment of the disclosed technology.

FIG. 5 shows an example of a pixel array based on an embodiment of the disclosed technology.

### DETAILED DESCRIPTION

Features, and certain advantages in connection with specific implementations of the disclosed technology disclosed in this patent document are described by example embodiments with reference to the accompanying drawings.

For sensing devices that capture colored images in colors based on the basic additive primary colors of red (R), green (G), blue (B) (RGB), the pixel size of the RGB sensing devices is reduced to increase or improve the spatial resolution of the captured images, and in such a case, the sensitivity in light sensing via each pixel with a reduced pixel size may decrease due to the reduced amount of captured light by each pixel.

In the case of infrared (IR) sensing devices, the infrared (IR) sensing devices can have a large Epi thickness to improve the sensitivity. However, the increase in the Epi thickness may lead to process limitations and an increase in cost.

The disclosed technology can address the issues discussed above by providing an image sensing device that includes a cavity resonance structure with dual meta lenses, thereby reducing or minimizing the Epi thickness.

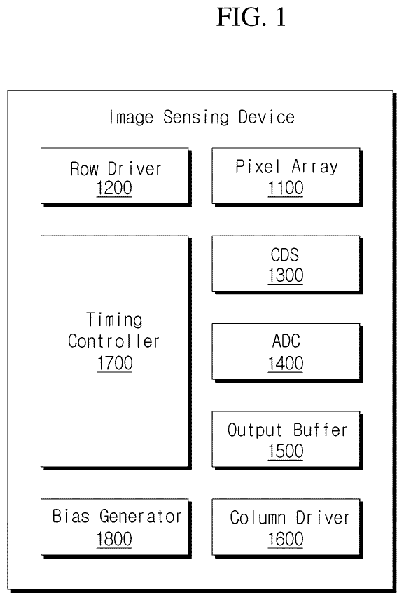

FIG. 1 is a block diagram of an image sensing device In an embodiment of the disclosed technology.

Referring to FIG. 1, an image sensing device based on an embodiment may include a pixel array 1100, a row driver 1200, a correlated double sampler (CDS) 1300, and an analog-digital converter (ADC) 1400, an output buffer 1500, a column driver 1600, a timing controller 1700, and a bias generator 1800. Here, each of the components of the image sensing device is just an example, and at least some of the components may be added or omitted as needed.

The pixel array 1100 may include a plurality of pixels arranged in a plurality of rows and in a plurality of columns. In the embodiment, the plurality of pixels may be arranged in a two-dimensional pixel array including rows and columns. In another embodiment, a plurality of unit image pixels may be arranged in a three-dimensional pixel array. The plurality of pixels may convert an optical signal into an electrical signal on a pixel basis or a pixel group basis, and pixels within a pixel group may share at least a specific internal circuit. The pixel array 1100 may receive a drive signal including a row selection signal, a pixel reset signal, a transmission signal, etc., from the row driver 1200. The pixel of the pixel array 1100 may receive a row selection signal by the driving signal. The pixel of the pixel array 1100 may be activated, by the drive signal, to perform operations corresponding to the row selection signal, the pixel reset signal, and the transmission signal.

The row driver 1200 may activate the pixel array 1100 such that specific operations are performed on the pixels included in the row based on commands and control signals supplied by the timing controller 1700. In the embodiment, the row driver 1200 may select at least one pixel arranged in at least one row of the pixel array 1100. The row driver 1200 may generate the row selection signal in order to select at least one row among the plurality of rows. The row driver 1200 may sequentially enable the pixel reset signal and the transmission signal for pixels corresponding to at least one selected row. Accordingly, an analog reference signal and analog image signal generated from each pixel of the selected row may be sequentially transmitted to the correlated double sampler 1300. Here, the reference signal may be an electrical signal provided to the correlated double sampler 1300 when a sensing node of the pixel (e.g., floating diffusion node) is reset. The image signal may be an electrical signal provided to the correlated double sampler 1300 when photocharges generated by the pixel is accumulated in the sensing node. The reference signal representing pixel-specific reset noise and the image signal representing the intensity of incident light may be collectively referred to as pixel signals.

A CMOS image sensor samples the pixel signal twice in order to remove the difference between two samples, so that correlated double sampling can be used such that unwanted offset values of the pixel such as fixed pattern noise are removed. As an example, the correlated double sampling compares pixel output voltages obtained before and after the photocharges generated by the pixels in response to the received incident light are accumulated in the sensing node, thereby removing unwanted offset values and measuring the pixel output voltage based only on the incident light. In the embodiment, the correlated double sampler 1300 may sequentially sample and hold the reference signal and image signal provided to each of a plurality of column lines from the pixel array 1100. Thus, the correlated double sampler 1300 may sample and hold the levels of the reference signal and image signal corresponding to each column of the pixel array 1100.

The correlated double sampler 1300 may transmit the reference signal and image signal of each column as a correlated double sampling signal to the ADC 1400 based on the control signal from the timing controller 1700.

The ADC 1400 may convert the correlated double sampling signal for each column output from the correlated double sampler 1300 into a digital signal and output it. In the embodiment, the ADC 1400 may be implemented as a ramp-compare type ADC. The ramp-compare type ADC may include a comparison circuit and a counter. The comparison circuit compares a ramp signal that rises or falls over time and an analog pixel signal. The counter performs a counting operation until the ramp signal matches the analog pixel signal. In the embodiment, the ADC 1400 may convert the correlated double sampling signal generated by the correlated double sampler 1300 for each of the columns into a digital signal and output it.

The ADC 1400 may include a plurality of column counters corresponding to the columns of the pixel array 1100, respectively. The columns of the pixel array 1100 may be connected to the column counters, respectively, and image data may be generated by converting the correlated double sampling signal corresponding to each column into a digital signal by using the column counters. According to another embodiment, the ADC 1400 may include one global counter and may convert the correlated double sampling signal corresponding to each column into a digital signal by using a global code provided by the global counter.

The output buffer 1500 may temporarily hold and output image data in units of each column provided from the ADC 1400. The output buffer 1500 may temporarily store the image data output from the ADC 1400 based on the control signal of the timing controller 1700. The output buffer 1500 may operate as an interface that compensates for a difference in transmission (or processing) speed between the image sensing device and another device connected to the image sensing device.

The column driver 1600 may select a column of the output buffer 1500 based on the control signal of the timing controller 1700 and may control the image data temporarily stored in the selected column of the output buffer 1500 to be output sequentially. In the embodiment, the column driver 1600 may receive an address signal from the timing controller 1700, and the column driver 1600 may generate a column selection signal based on the address signal and may select the column of the output buffer 1500, thereby controlling the image data to be output from the selected column of the output buffer 1500 to the outside.

The timing controller 1700 may control at least one of the row driver 1200, the correlated double sampler 1300, the ADC 1400, the output buffer 1500, the column driver 1600, and the bias generator 1800.

The timing controller 1700 may provide a clock signal required for the operation of each component of the image sensing device, the control signal for timing control, the address signal for selecting rows or columns, and a signal for controlling the level of a bias voltage applied to the pixel array 1100, etc., to at least one of the row driver 1200, the correlated double sampler 1300, the ADC 1400, the output buffer 1500, the column driver 1600, and the bias generator 1800. In an embodiment, the timing controller 1700 may include a logic control circuit, a phase lock loop (PLL) circuit, a timing control circuit, and a communication interface circuit, etc.

The bias generator 1800 may generate a bias voltage to suppress dark current which is generated in the pixel of the pixel array 1100 and may supply the bias voltage to the pixel array 1100.

The bias voltage may be determined during a wafer probe test of the image sensing device and may be stored in one-time programmable memory (OTP). For example, the bias voltage has a value capable of minimizing unnecessary power consumption without degrading the performance of the image sensing device and of maximizing an effect of suppressing the dark current. The value of the bias voltage can be experimentally determined.

The bias generator 1800 may generate a voltage corresponding to the bias voltage stored in the OTP memory. In an embodiment, the OTP memory may be included in the image sensing device, and in particular may be included in the bias generator 1800.

In an embodiment, the bias voltage may include a plurality of values.

For example, the plurality of values may correspond to a plurality of operation modes of the image sensing device, respectively. The dark currents generated at low and high illuminances may be different from each other, and the bias voltage supplied by the bias generator 1800 in order to effectively suppress the dark current in each environment may vary depending on the mode.

In some implementations, the plurality of values may correspond to a plurality of regions of the pixel array 1100, respectively. The dark currents generated according to the position of the pixel on the pixel array 1100 may be different from each other, and the bias voltage supplied by the bias generator 1800 in order to effectively suppress the dark current regardless of the position of the pixel may vary depending on the region.

The bias voltage may be a negative voltage with a negative sign. However, the scope of the disclosed technology is not limited thereto.

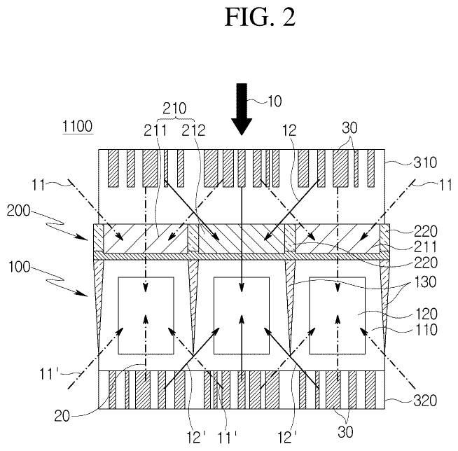

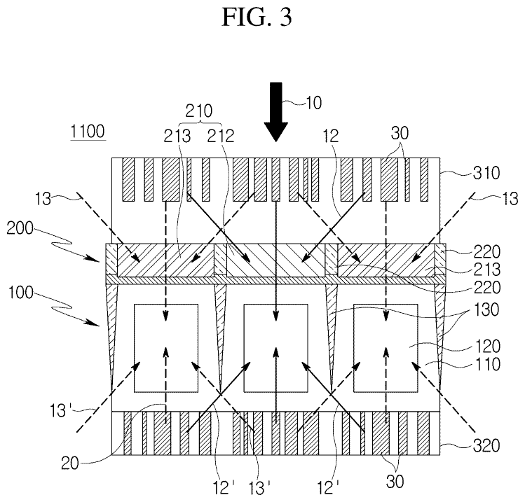

FIGS. 2 and 3 show examples of a pixel array based on some embodiments of the disclosed technology.

Referring to FIGS. 2 and 3, the image sensing device may be constructed as an RGB image sensing device using the pixel array 1100 in some implementations.

In an embodiment, the pixel array 1100 may include a lower layer 100, an upper layer 200, a first meta-lens layer 310 on the top of the upper layer 200 to receive incident light, and a second meta-lens layer 320 on the bottom of the lower layer 100 to redirect light towards the lower layer 100.

The lower layer 100 may include a substrate 110, a plurality of photo sensors or photodetectors 120 such as photodiodes 120 supported by the substrate 110, and a first isolation region 130 formed between adjacent photo sensors or photodetectors 120 to isolate the photo sensors or photodetectors 120.

In an embodiment, the substrate 110 may include a single crystalline semiconductor material such as silicon (Si).

In an embodiment, the photodiode 120 may be formed in one region of the substrate 110, and an N-type impurity region and a P-type impurity region may be stacked in a vertical direction. The N-type impurity region and the P-type impurity region may be formed through an ion implantation process.

The first isolation region 130 may be formed between the photodiodes 120. The first isolation region 130 may include, for a Si substrate 110, at least one of a silicon oxynitride layer (SiON), a silicon oxide layer (SiO), or a silicon nitride layer (SiN).

The upper layer 200 may be formed over the lower layer 100 and may include a plurality of color filters 210 located on top of the photosensors 120, respectively, to filter incident light that is respectively received by the photosensors 120.

In the illustrated example, the plurality of color filters 210 is formed over the substrate 110 and may include a red color filter 211 to transmit light of a certain red color to the corresponding photosensor for sensing while blocking light of other colors, a green color filter 212 to transmit light of a certain green color to the corresponding photosensor for sensing while blocking light of other colors, and a blue color filter 213 to transmit light of a certain blue color to the corresponding photosensor for sensing while blocking light of other colors. This RGB color filing design is an example only the color and type of the color filters are not limited to this: other color filter patterns may be used in such color imaging sensing devices.

A second isolation region 220 may be formed between the color filters 210.

The second isolation region 220 may include at least one of a silicon oxynitride layer (SiON), a silicon oxide layer (SiO), and a silicon nitride layer (SiN).

The first meta-lens layer 310 may be formed over the upper layer 200 and may serve to focus incident light 10 on each of the color filters 210 on top of the photodetectors 120.

In an embodiment, the first meta-lens layer 310 may include a plurality of nanostructures configured to focus the incident light 10 to a specific point. The first meta-lens layer 310 can refract the incident light 10 through the nanostructure so that the light can be focused to a specific point.

In an embodiment, the first meta-lens layer 310 may refract the incident light 10 such that: a red wavelength light ray 11 of the incident light 10 is focused on the red color filter 211; a green wavelength light ray 12 of the incident light 10 is focused on the green color filter 212; and a blue wavelength light ray 13 of the incident light 10 is focused on the blue color filter 213.

In an embodiment, the first meta-lens layer 310 may include a material with higher transmittance than that of the second meta-lens layer 320.

The second meta-lens layer 320 is formed below the lower layer 100 and may serve to scatter or reflect the incident light toward the photodiode 120.

In an embodiment, the second meta-lens layer 320 may include a plurality of nanostructures configured to scatter or reflect incident light. The second meta-lens layer 320 may reflect the incident light that passes through the lower layer 100 to a specific point through the nanostructure.

In an embodiment, the second meta-lens layer 320 may reflect light that passes through the lower layer 100.

In an embodiment, the second meta-lens layer 320 may reflect the incident light such that: the red wavelength light ray of the incident light passing through the lower layer 100 is focused on the photodiode 120 below the red color filter 211 (11′), the green wavelength light ray of the incident light passing through the lower layer 100 is focused on the photodiode 120 below the green color filter 212 (12′); and the blue wavelength light ray of the incident light passing through the lower layer 100 is focused on the photodiode 120 below the blue color filter 213 (13′).

In order for a cavity resonance phenomenon to occur, the light is in phase during a round trip, and a cavity length for the occurrence of the cavity resonance phenomenon can be expressed as follows:

$$L = 2 πλ sin θ \qquad Equation ( 1 )$$

For the purpose of the cavity resonance, an Epi thickness is changed for each wavelength by adjusting a refraction angle at which each wavelength is refracted. That is, the refraction angle is adjusted within an angle at which total reflection occurs from the first isolation region 130 (e.g., deep trench isolation (DTI)), so that a structure having the same cavity length for each wavelength can be formed. In some implementations, the structure can be designed in consideration of the DTI total reflection angle to minimize crosstalk (Xtalk) between the pixels. In some implementations, the Epi thickness may be the thickness of a thin film of crystals grown on another crystal.

In an embodiment, when an angle formed between a surface of the second meta-lens layer 320 and the incident light is a right angle, the second meta-lens layer 320 may direct the reflected light from the incident light toward the first isolation region 130 on both sides of the photodiode 120.

In an embodiment, the second meta-lens layer 320 may include a material with lower transmittance than that of the first meta-lens layer 310.

The cavity resonance structure is formed through the first meta-lens layer 310 and the second meta-lens layer 320, the Epi thickness can be reduced.

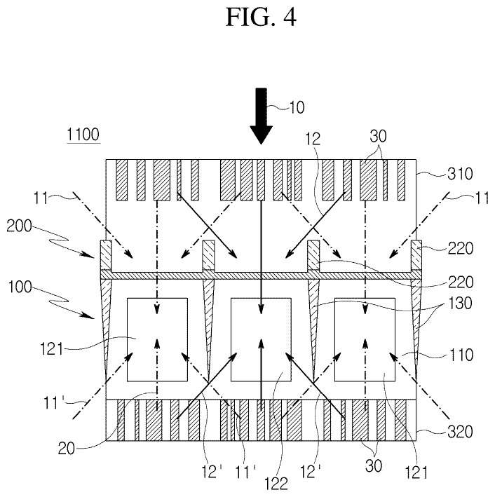

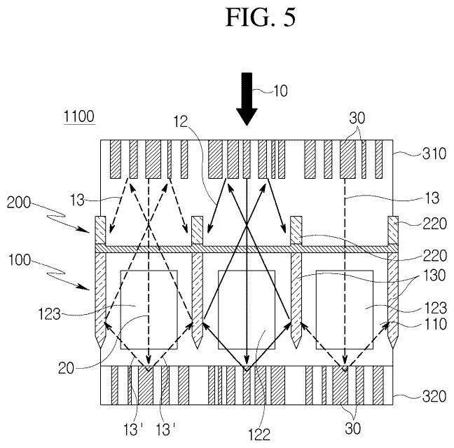

FIGS. 4 and 5 show examples of a pixel array based on some embodiments of the disclosed technology.

Referring to FIGS. 4 and 5, the image sensing device in an embodiment may be an RGB image sensing device.

In an embodiment, the pixel array 1100 may include the lower layer 100, the upper layer 200, the first meta-lens layer 310, and the second meta-lens layer 320.

The lower layer 100 may include the substrate 110, the plurality of photodiodes 120, and the first isolation region 130.

In an embodiment, the substrate 110 may include a single crystalline silicon (Si) material.

In an embodiment, the plurality of photodiodes 120 may be formed in one region of the substrate 110, and an N-type impurity region and a P-type impurity region may be stacked in a vertical direction. The N-type impurity region and the P-type impurity region may be formed through an ion implantation process.

In an embodiment, the plurality of photodiodes 120 may include a first photodiode 121 that receives light with a red wavelength, a second photodiode 122 that receives light with a green wavelength, and a third photodiode 123 that receives light with a blue wavelength.

The first isolation region 130 may be formed between the photodiodes 120. The first isolation region 130 may include at least one of a silicon oxynitride layer (SiON), a silicon oxide layer (SiO), and a silicon nitride layer (SiN).

The upper layer 200 may be formed over the lower layer 100.

The upper layer 200 may include the second isolation region 220 formed over the first isolation region 130.

The second isolation region 220 may include at least one of a silicon oxynitride layer (SiON), a silicon oxide layer (SiO), and a silicon nitride layer (SiN).

Since the image sensing devices based on some embodiments shown in FIGS. 4 and 5 do not include a color filter, the Epi thickness can be reduced compared to the image sensing devices based on some embodiments shown in FIGS. 2 and 3. The image sensing devices based on some embodiments shown in FIGS. 4 and 5 can focus the incident light through the meta-lens layer without a color filter.

The first meta-lens layer 310 may be formed over the upper layer 200 and may serve to focus the incident light 10 on each of the photodiodes 120.

In an embodiment, the first meta-lens layer 310 may include a plurality of nanostructures configured to focus the incident light 10 to a specific point. The first meta-lens layer 310 can refract the incident light 10 through the nanostructure so that the light can be focused to a specific point.

In an embodiment, the first meta-lens layer 310 may refract the incident light 10 such that: the red wavelength light ray 11 of the incident light 10 is focused on the first photodiode 121; the green wavelength light ray 12 of the incident light 10 is focused on the second photodiode 122; and the blue wavelength light ray 13 of the incident light 10 is focused on the third photodiode 123.

In an embodiment, the first meta-lens layer 310 may include a material with higher transmittance than that of the second meta-lens layer 320.

The second meta-lens layer 320 is formed below the lower layer 100 and may serve to scatter or reflect the incident light toward the photodiode 120.

In an embodiment, the second meta-lens layer 320 may include a plurality of nanostructures that scatters or reflects incident light. The second meta-lens layer 320 may reflect the incident light passing through the lower layer 100 to a specific point through the nanostructure.

In an embodiment, the second meta-lens layer 320 may reflect light that passes through the lower layer 100.

In an embodiment, the second meta-lens layer 320 may reflect the incident light such that: the red wavelength light ray of the incident light passing through the lower layer 100 is focused on the first photodiode 121; the green wavelength light ray of the incident light passing through the lower layer 100 is focused on the second photodiode 122; and the blue wavelength light ray of the incident light passing through the lower layer 100 is focused on the third photodiode 123. That is, the incident light passing through the lower layer 100 may be reflected by the second meta-lens layer 320 and may be focused on the photodiode of the adjacent pixel corresponding to each wavelength (e.g., red, green, blue).

Referring to FIG. 5, In an embodiment, when an angle formed between a surface of the second meta-lens layer 320 and the incident light is a right angle, the second meta-lens layer 320 may direct the reflected light from the incident light which has transmitted through the lower layer 100, toward the first isolation region 130 on both sides of the photodiode 120. For example, when the blue wavelength light ray of the incident light passing through the lower layer 100 is incident in a direction perpendicular to a surface of the second meta-lens layer 320, the second meta-lens layer 320 may direct reflected light 13′ with the blue wavelength toward the first isolation region 130 on both sides of the third photodiode 123. When the remaining red wavelength rays and green wavelength rays of the incident light passing through the lower layer 100 are incident in a direction perpendicular to the surface of the second meta-lens layer 320, the second meta-lens layer 320 may direct reflected light corresponding to each of the red, green, and blue wavelengths such that the reflected light is directed to the first isolation region 130 on both sides of the photodiode.

In an embodiment, the second meta-lens layer 320 may include a material with lower transmittance than that of the first meta-lens layer 310.

In an embodiment, the image sensing device may be an infrared sensing device and may include an infrared filter instead of the color filter in FIG. 2. Since the remaining components of the infrared sensing device is the same as the above-described components of the image sensing device of FIG. 2, detailed descriptions thereof will be omitted.

In an implementation, the Epi thickness of the infrared sensing device is larger than that of an RGB sensing device. However, the Epi thickness may be reduced through the first meta-lens layer 310 and the second meta-lens layer 320, thereby minimizing noise caused by other wavelengths.

While various embodiments have been described above, variations and improvements of the disclosed embodiments and other embodiments may be made based on what is described or illustrated in this document.

What is claimed is:

1. An image sensing device comprising:
a lower layer including a substrate and a plurality of photodetectors;
an upper layer disposed over the lower layer;
a first meta-lens layer disposed over the upper layer and configured to focus incident light; and
a second meta-lens layer disposed below the lower layer and configured to scatter or reflect the incident light toward the photodetectors.

2. The image sensing device of claim 1, wherein the lower layer comprises:
the substrate;
the plurality of photodetectors formed in one region of the substrate; and
a plurality of first isolation regions formed between adjacent photodetectors of the plurality of photodetectors.

3. The image sensing device of claim 1, wherein the upper layer comprises:
a plurality of color filters formed over the substrate; and
a plurality of second isolation regions formed between adjacent color filters of the plurality of color filters.

4. The image sensing device of claim 3,
wherein the plurality of color filters comprises one or more red color filters, one or more green color filters, and one or more blue color filters, and
wherein the first meta-lens layer comprises a plurality of nanostructures to refract the incident light such that light rays of the incident light at a red wavelength are focused onto the one or more red color filters, light rays of the incident light at a green wavelength are focused onto the one or more green color filters, and light rays of the incident light at a blue wavelength are focused onto the one or more blue color filters.

5. The image sensing device of claim 4, wherein the second meta-lens layer comprises a plurality of nanostructures to reflect, toward the lower layer, the incident light that passes through the lower layer.

6. The image sensing device of claim 5, wherein, in a case that the incident light is incident on a surface of the second meta-lens layer at a right angle, the second meta-lens layer directs the light reflected from the second meta-lens layer toward sidewalls of first isolation regions formed between adjacent photodetectors of the plurality of photodetectors.

7. The image sensing device of claim 4, wherein the second meta-lens layer reflects the incident light such that the light rays of the incident light at the red wavelength reflected from the second meta-lens layer and passing through the lower layer are focused onto the photodetector below the red color filter, the light rays of the incident light at the green wavelength reflected from the second meta-lens layer and passing through the lower layer are focused onto the photodetector below the green color filter, and the light rays of the incident light at the blue wavelength reflected from the second meta-lens layer and passing through the lower layer are focused onto the photodetector below the blue color filter.

8. An image sensing device comprising:
a lower layer including a substrate and a plurality of photodetectors;
an upper layer disposed over the lower layer;
a first meta-lens layer disposed over the upper layer and configured to focus incident light; and
a second meta-lens layer disposed below the lower layer and configured to scatter or reflect the incident light toward the or reflect the incident light from the photodetectors,
wherein the first meta-lens layer and the second meta-lens layer have different transmittances from each other.

9. An image sensing device comprising:
a first layer including a substrate and a plurality of photodetectors;
a second layer disposed over the first layer and including a plurality of infrared filters;
a first meta-lens layer disposed over the second layer and configured to focus incident light onto each of the infrared filters; and
a second meta-lens layer disposed below the first layer and configured to scatter or reflect the incident light toward the photodetector.

10. The image sensing device of claim 9, wherein the first layer comprises:
the substrate;
the plurality of photodetectors formed in one region of the substrate; and
a plurality of first isolation regions formed between adjacent photodetectors of the plurality of photodetectors.

11. The image sensing device of claim 9, wherein the second layer comprises:
the plurality of infrared filters formed over the substrate; and
a plurality of second isolation regions formed between adjacent infrared filters of the plurality of infrared filters.

12. The image sensing device of claim 9, wherein the first meta-lens layer comprises a plurality of nanostructures to refract the incident light such that the incident light is focused onto each of the infrared filters.

13. The image sensing device of claim 12, wherein the second meta-lens layer comprises a plurality of nanostructures to reflect, toward the first layer, the incident light that passes through the first layer.

14. An image sensing device comprising:
a lower layer including a substrate and a plurality of photodetectors;
an upper layer disposed over the lower layer;
a first meta-lens layer disposed over the upper layer and configured to focus incident light onto each of the photodetectors; and
a second meta-lens layer disposed below the lower layer and configured to scatter or reflect the incident light toward the photodetector.

15. The image sensing device of claim 14, wherein the lower layer comprises:
the substrate;
the plurality of photodetectors formed in one region of the substrate; and
a plurality of first isolation regions formed between adjacent photodetectors of the plurality of photodetectors.

16. The image sensing device of claim 15, wherein the upper layer comprises a plurality of second isolation regions formed over the plurality of first isolation regions.

17. The image sensing device of claim 14, wherein the plurality of photodetectors comprises:
a first photodetector that receives light with a red wavelength;
a second photodetector that receives light with a green wavelength; and
a third photodetector that receives light with a blue wavelength,
wherein the first meta-lens layer comprises a plurality of nanostructures to refract the incident light such that light rays of the incident light at the red wavelength are focused onto the first photodetector, light rays of the incident light at the green wavelength are focused onto the second photodetector, and light rays of the incident light at the blue wavelength are focused onto the third photodetector.

18. The image sensing device of claim 17, wherein the second meta-lens layer comprises a plurality of nanostructures to reflect, toward the lower layer, the incident light that passes through the lower layer.

19. The image sensing device of claim 17, wherein the second meta-lens layer reflects the incident light such that the light rays of the incident light at the red wavelength reflected from the second meta-lens layer and passing through the lower layer are focused onto the first photodetector, the light rays of the incident light at the green wavelength reflected from the second meta-lens layer and passing through the lower layer are focused onto the second photodetector, and the light rays of the incident light at the blue wavelength reflected from the second meta-lens layer and passing through the lower layer are focused onto the third photodetector.
